(19) United States
(12) Patent Application Publication
(10) Pub. No.: US 2003/0087187 A1
(43) Pub. Date: May 8, 2003

(54) Thick film photoresist layer laminate, method of manufacturing thick film resist pattern, and method of manufacturing connecting terminal

(75) Inventors: Koji Saito, Kawasaki-shi (JP); Yasushi Washio, Kawasaki-shi (JP); Toshiki Okui, Kawasaki-shi (JP)

Correspondence Address: HOFFMANN & BARON, LLP, 6900 JERICHO TURNPIKE, SYOSSET, NY, 11791, US

(73) Assignee: Tokyo Ohka Kogyo Co., Ltd.

(21) Appl. No.: 10/283,513

(22) Filed: Oct. 30, 2002

(30) Foreign Application Priority Data
Nov. 2, 2001 (JP) 2001-338474

(51) Int. Cl. G03F 7/038

(52) U.S. Cl. 430/270.1; 430/311; 430/325

(57) ABSTRACT

There is provided a means capable of forming a high-accuracy resist pattern by the reaction of a resist composition with high sensitivity in a thin film photoresist layer used in the manufacture of a connecting terminal. Using a thick film photoresist layer laminate comprising a substrate (a), and a thick film photoresist layer (b) containing a resin whose alkali solubility changes due to the action of an acid, and an acid generator, which are laminated via a shield layer (c) which prevents the substrate (a) from contacting the thick film photoresist layer (b), a resist pattern is formed and a connecting terminal is then formed using a resist pattern.

### BACKGROUND OF THE INVENTION

1. Field of the Invention

The present invention relates to a thick film photoresist layer laminate, a method of manufacturing a thick film resist pattern, and a method of manufacturing a connecting terminal.

More particularly, the present invention relates to a thick film photoresist layer laminate, which is suited for the manufacture of a connecting terminal used to mount semiconductors or electronic parts on a circuit board, a method of manufacturing a thick film resist pattern, and a method of manufacturing a connecting terminal.

2. Description of the Related Art

Along with the size reduction of electronic instruments, the large scale integration of LSI's has recently made rapid progress. To mount LSI's in electronic instruments, a multi-pin thin film mounting method, is used, which comprises providing a connecting terminal comprising an extruding electrode on the surface of a substrate such as base.

In the multi-pin thin film mounting method, a connecting terminal comprising a bump protruding from a substrate, or a connecting terminal comprising a pole brace, which is referred to as a metal post, protruding from a substrate and a solder ball formed thereon is used.

The bump or metal post can be formed, for example, by forming a thick film resist layer having a thickness of about 5 μm or more on the substrate, exposing to light through a predetermined mask pattern, developing to form a resist pattern in which a portion capable of forming a connecting terminal is selectively removed (peeled), embedding a conductor such as copper in the portion (non-resist portion) thus removed, and finally removing the resist pattern in the vicinity of the portion.

For example, Japanese Patent Application, First Publication No. Hei 10-207057A, Japanese Patent Application, First Publication No. 2000-39709A and Japanese Patent Application, First Publication No. 2000-66386A disclose photoresist compositions for thick films used for forming a thick film photoresist layer. However, since these conventional photoresist compositions for thick films comprise a polymeric compound, a photopolymerizable monomer and a photopolymerization initiator, a large amount of the photopolymerization initiator has been required to sufficiently react the entire photoresist layer. However, when the amount of the photopolymerization initiator becomes large, the compatibility of the respective constituent components in the thick film photoresist composition is reduced, which causes such problems that the resulting resist pattern has a trapezoidal cross section and poor development occurs during the development and, moreover, the plating solution resistance of the thick film photoresist layer is lowered. Therefore, the above photoresist compositions were not satisfactory for the manufacture of connecting terminals. Thus, a photoresist composition for thick films, which is suited for the manufacture of connecting terminals, has been required.

As a high-sensitivity photosensitive resin composition, a chemical amplification type resist composition using an acid generator is known.

In the chemical amplification type resist composition, an acid is generated by the acid generator as a result of irradiation with radiation. The chemical amplification type resist composition is designed so that a heat treatment after exposure promotes the generation of the acid and changes the alkali solubility of a base resin in a resist. The resist composition wherein a substance, which is insoluble in an alkali, becomes soluble in the alkali is referred to as a positive type resist composition, while the resist composition wherein a substance, which is soluble in an alkali, becomes insoluble in the alkali is referred to as a negative type resist composition.

As described above, in the chemical amplification type resist composition, the photoreaction efficiency (amount of reaction per photon) achieves remarkably high sensitization as compared with conventional resists.

However, when a thick film photoresist layer is formed by using a chemical amplification type resist, there arises the problem that the required high-accuracy resist pattern characteristics cannot be obtained, unlike the case where a conventional resist layer having a thickness of 1 μm or less is formed.

### BRIEF SUMMARY OF THE INVENTION

Under the circumstances described above, the present invention has been made, and an object thereof is to provide a means capable of forming a high-accuracy resist pattern by the reaction of a resist composition with high sensitivity in a thick film photoresist layer used in the manufacture of connecting terminals.

The present inventors have carried out studies and found that metal such as aluminum or copper used in a substrate such as a base inhibits the action of an acid on the resin in a chemical amplification type thick film photoresist layer, and thus completed the present invention.

That is, a first aspect of the present invention is directed to a thick film photoresist layer laminate comprising:

a substrate (a), and

a thick film photoresist layer (b) containing a resin whose alkali solubility changes due to an action of an acid, and an acid generator, which are laminated via a shield layer (c) which prevents the substrate (a) from contacting the thick film photoresist layer (b).

A second aspect of the present invention is directed to a method of manufacturing a thick film resist pattern, which comprises the steps of obtaining a thick film photoresist layer laminate comprising a substrate (a), an a thick film photoresist layer (b) containing a resin whose alkali solubility changes due to an action of an acid, and an acid generator, which are laminated via a shield layer (c) which prevents the substrate (a) from contacting the thick film photoresist layer (b); selectively irradiating the laminate with radiation; and developing the laminate after the irradiation step to obtain a thick film resist pattern.

A third aspect of the present invention is directed to a method of manufacturing a connecting terminal, which comprises the step of forming a connecting terminal made of a conductor at a non-resist portion of the thick film resist pattern obtained by using the method of manufacturing a thick film resist pattern.

### DETAILED DESCRIPTION OF THE INVENTION

The present invention will now be described in detail.

(a) Substrate

The substrate is not specifically limited as far as a connecting terminal can be manufactured, and conventionally known ones can be used including, for example, substrates comprising a base for electronic parts and a predetermined wiring pattern formed thereon.

Examples of the base include bases made of metals such as copper, chromium, iron or aluminum, and glass bases. As the material of a wiring pattern, for example, copper, solder, chromium, aluminum, nickel and gold can be used.

In the present invention, an effect that the metal would exert on the thick film photoresist layer (b) is blocked by the shield layer (c) provided between the substrate (a) and the thick film photoresist layer (b). Therefore, lowering of the sensitivity of the thick film photoresist layer (b) can be prevented without inhibiting the action of an acid generated by irradiation with radiation in the thick film photoresist layer (b), thus making it possible to provide a high intrinsic sensitivity of the chemical amplification type resist composition.

Therefore, the present invention is preferably applied to the substrate (a) wherein the side, at which the thick film resist layer is formed, is made of metal. Particularly, since copper exerts a large effect with an acid, the present invention is more preferably applied to a substrate made of copper

(b) Thick Film Photoresist Layer

The thick film photoresist layer can be formed from a so-called chemical amplification type resist composition containing a resin (base resin) whose alkali solubility changes due to the action of an acid, and an acid generator.

The chemical amplification type resist composition which can be used in the present invention is not specifically limited and it may be either of positive or negative type resist composition.

The amount of the acid generator is not specifically limited, but is within a range from about 0.01 to 20.0 parts by weight based on 100 parts by weight of the base resin.

Specific examples of the negative chemical amplification type resist composition are preferably those containing a novolak resin (A), a plasticizer (B), a crosslinking agent (C) and an acid generator (D).

The component (A) is preferably an alkali-soluble novolak resin because of its good definition and excellent heat resistance.

The component (B) is preferably an alkali-soluble acrylic resin or an alkali-soluble vinyl resin because flexibility in plating is required.

The component (C) is preferably an alkoxymethylated amino resin because of its very strong crosslinkability. The alkoxymethylated amino resin is preferably at least one selected from methoxymethylated melamine resin, ethoxymethylated melamine resin, propoxymethylated melamine resin and butoxymethylated melamine resin because it has high stability and is free from contamination of plating.

The component (D) is preferably a triazine compound because of its remarkably high reaction rate.

This negative chemical amplification type resist composition is preferably applied onto a base after dissolving in an organic solvent in order to form a thick film photoresist layer on a substrate. The organic solvent is mixed in an amount of about 20 to 80% by weight based on the mixture. If necessary, it is possible to mix with surfactants, auxiliary adhesives, fillers, colorants, viscosity modifiers, defoamers and other additives.

The thickness of the thick film photoresist layer (b) is set to 5 μm or more for the following reason. That is, when the thickness is less than 5 μm, the layer is too thin to form a connecting terminal. This thickness can vary depending on the height (thickness) of the connecting terminal to be manufactured, but is preferably set within a range from 5 to 150 μm, and more preferably from 10 to 120 μm. If a bump is formed, the thickness is set within a range from about 10 to 30 μm, while the thickness is set within a range from about 50 to 120 μm if a metal post is formed.

(c) Shield Layer

The shield layer (c) does not react with either the substrate (a) or the thick film photoresist layer (b) and is not mixed with them. The material thereof is not specifically limited as far as it can prevent the substrate (a) from contacting the thick film photoresist layer (b).

However, since the shield layer (c) is removed together with an alkali-soluble portion of the thick film resist layer during alkali development in the manufacture of the resist pattern, the shield layer is preferably made of an alkali-soluble material. To form the shield layer (c), the material preferably has good film-forming properties.

For example, it is preferable to use a material containing, as a main component, an alkali-soluble novolak resin, an alkali-soluble acrylic resin, an alkali-soluble vinyl resin or an alkali-soluble hydroxystyrene resin. These resins can be used alone or in combination thereof.

By providing the shield layer (c), it is possible to prevent the substrate (a) from affecting on the thick film photoresist layer (b). If copper is present on the substrate (a), the effect due to its oxide film is eliminated, thereby making it possible to obtain a stable rectangular pattern upon formation of the pattern of the thick film photoresist layer (b).

If the resin is a thermosetting resin, or a resin cured by irradiation, such as an ultraviolet-curable resin, a crosslinking agent such as a melamine resin is preferably included.

Since the inclusion of the crosslinking agent such as a melamine resin can improve the film formability, it is preferable to include this crosslinking agent when using a resin containing a resin having poor film formability as a main component.

The crosslinking agent is preferably mixed in an amount within a range from about 5 to 30 parts by weight based on 100 parts by weight of the resin, in view of the effect it provides.

In the formation of the shield layer (c), these materials are used after dispersing or dissolving in an organic solvent in order to adjust the viscosity.

The organic solvent is not specifically limited as far as it can uniformly disperse or dissolve the other compounding materials, and conventionally known solvents can be used.

Specific examples of the preferred materials to constitute the shield layer (c), include the following first and second shield layer materials as described in Japanese Patent Application, First Publication No. Hei 9-292715A and Japanese Patent Application, First Publication No. Hei 10-228113A.

These materials have the characteristics that they can absorb the radiation used during the exposure. Therefore, they can absorb radiation, which would otherwise be transmitted to the thick film photoresist layer (b) and cause irregular refraction on the surface of the substrate (a). Therefore, by providing a shield layer (c) made of the shield layer material, a rectangular resist pattern can be formed more closely to a mask pattern.

(First Shield Layer Material)

The first shield layer contains:

(1-1) an ultraviolet absorber selected from benzophenone compounds having at least one amino group or alkyl-substituted amino group and azomethine compounds having at least one amino group or alkyl-substituted amino group, and

(2-1) a crosslinking agent selected from nitrogen-containing compounds having at least two amino groups substituted with a hydroxyalkyl group and/or an alkoxyalkyl group in a weight ratio of 1:1 to 1:10.

In view of high absorptivity of radiation such as ultraviolet light, the component (1-1) is preferably a benzophenone compound represented by the general formula (1):

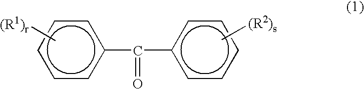

wherein R¹ and R² each represents an amino group, an alkyl-substituted amino group or a hydroxyl group, at least one of which being an amino group or alkyl-substituted amino group, and r and s represent 1 or 2.

Other preferred examples of the component (1-1) include an azomethine compound represented by the general formula: Ar—CH═N—Ar′ (wherein Ar and Ar′ each represents an aryl group having a substituent selected from an amino group, alkyl-substituted amino group, hydroxyl group, nitro group, halogen atom, alkyl group and alkoxy group, at least one of the substituents of Ar and Ar′ being an amino group or an alkyl-substituted amino group).

The component (1-1) is preferably an azomethine compound represented by the following general formula (2):

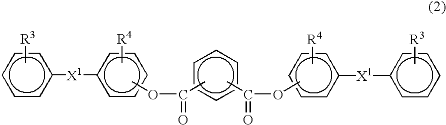

wherein R³ and R⁴ each represents a substituent selected from an amino group, alkyl-substituted amino group, hydroxyl group, nitro group, halogen atom, alkyl group and alkoxy group, at least one of them being an amino group or an alkyl-substituted amino group, and X¹ represents a linking group represented by —CH═N— or —N═CH—.

In view of high absorptivity power of radiation such as ultraviolet light, the component (2-1) is preferably a melamine derivative wherein the hydrogen atoms of the amino group are substituted with methylol groups and/or an alkoxymethyl groups.

(Second Shield Layer Material)

The second shield layer material contains:

(1-2) a crosslinking agent selected from nitrogen-containing compounds having at least two amino groups substituted with a hydroxyalkyl group and/or an alkoxyalkyl group, and

(2-2) a polymer or copolymer obtained by using, as at least a portion of the monomers, an ester of at least one hydroxy compound selected from bisphenylsulfones and benzophenones having at least one hydroxyl group and acrylic acid or methacrylic acid.

The second shield layer material preferably contains (3-2) a substance with high light absorptivity in view of a reduction of the effect of irregular refraction of the substrate surface.

The component (1-2) is preferably a melamine or benzoguanamine derivative wherein the hydrogen atoms of the amino groups are substituted with methylol groups and/or alkoxymethyl groups.

The component (3-2) is preferably at least one polyhydroxy compound having at least two hydroxyl groups selected from bisphenylsulfones, bisphenylsulfoxides and benzophenones in view of a reduction of the effect of irregular refraction.

In the second shield layer material, the weight ratio of the component (1-2) to the component (2-2) is preferably within a range from 40:60 to 90:10 in view of a balance between the effect of inhibiting reflections, conformality, inhibition of sublimation and coatability.

The content of the component (3-2) is preferably within a range from 3 to 30% by weight based on the total weight of the components (1-2), (2-2) and (3-2).

The thickness of the shield layer (c) is preferably set to 0.01 μm or more, and more preferably 0.2 μm or more. The upper limit is not specifically limited, but is preferably set to 5 μm or less, and more preferably 2 μm or less.

A resist pattern is formed on the thick film photoresist layer (b) by selectively irradiating the thick film photoresist layer (b) with radiation through a predetermined mask pattern, heating to generate an acid in the chemical amplification type resist composition, and uniformly reacting the acid with the upper and lower portions of the resist layer due to diffusion of the acid caused by heating, resulting in the formation of a rectangular pattern.

Upon heating, it is not preferred that the shield layer (c) be too thin, for the reason, that the so-called mixing phenomenon may occur, wherein the material constituting the substrate (a), which contacts the shield layer (c), or the material constituting the thick film photoresist layer (b), mixes with the material constituting the shield layer (c), and thus making it impossible for the shield layer to fulfil its desired function.

Although a shield layer (c) having a thickness of more than 5 μm can be provided, there is no substantial difference in effect as compared with a shield layer having a thickness of 5 μm and, therefore, it is uneconomical. It is also disadvantageous in that it requires much labor in the step of removing the resist pattern and the shield layer (c) after plating.

The thick film photoresist layer laminate of the present invention can be manufactured, for example, in the following manner.

A shield layer material is applied onto a substrate (a) and, if necessary, an organic solvent is removed with heating to form a shield layer (c). Then, a chemical amplification type photoresist composition is applied thereon and, if necessary, an organic solvent is removed with heating to form a thick film photoresist layer (b), thus obtaining a thick film photoresist layer laminate comprising the substrate (a) and the thick film photoresist layer (b), which are laminated via the shield layer (c).

In order to form a resist pattern using the thick film photoresist layer (b) thus formed, the thick film photoresist layer (b) is selectively irradiated with radiation through a predetermined mask pattern and generation and diffusion of an acid are accelerated by heating, thereby changing the alkali solubility of the portion of the thick film photoresist layer (b) irradiated with the radiation.

Then, the development is carried out using a predetermined alkali developing solution to remove the alkali-soluble portion of the thick film photoresist layer (b) and the shield layer (c) under the thick film photoresist layer, thus obtaining the desired resist pattern. Alternatively, the alkali-soluble portion of the thick film photoresist layer (b) is removed by using the alkali developing solution and the shield layer (c) under the thick film photoresist layer is removed by ashing to obtain the desired resist pattern.

A conductor such as a metal is then embedded in the non-resist portion (portion removed by the alkali developing solution) of the resist pattern thus obtained by plating to form a connecting terminal such as a bump or a metal post.

Finally, the remaining resist pattern and the shield layer (c) under the resist pattern are removed by using a remover in accordance with a conventional procedure.

As described above, in the present invention, since the shield layer (c) is provided between the substrate (a) and the thick film photoresist layer (b), it is possible to prevent the metal contained in the substrate (a) from inhibiting the action of an acid generated by irradiation with radiation in the thick film photoresist layer (b).

As a result, high-accuracy resist pattern characteristics can be obtained.

### EXAMPLES

The following Examples further illustrate the present invention in detail, but the present invention is not limited thereto.

<Preparation of Shield Layer Material>

### Synthesis Example 1

3 g of 4,4′-bis(diethylamino)benzophenone as the ultraviolet absorber (1-1), 5 g of a melamine derivative wherein a melamine ring is substituted with 3.7 methoxymethyl groups on average (manufactured by SANWA CHEMICAL CO., LTD. under the trade name of Mx-750) as the crosslinking agent (2-1) and 5 g of 2,2′,4,4′-tetrahydroxybenzophenone as the additive were dissolved in 150 g of propylene glycol monomethyl ether acetate and 1000 ppm of a fluorine surfactant (manufactured by Sumitomo 3M Co., Ltd. under the trade name of Fc-430) was further dissolved therein, and then the mixture was filtered through a membrane filter having a pore diameter of 0.2 μm to prepare a shield layer material.

<Preparation of Chemical Amplification Type Resist Composition (Negative)>

### Synthesis Example 2

(A) 75 parts by weight of an alkali-soluble novolak resin having a weight-average molecular weight of 15000 wherein the low molecular region was removed, which is obtained by mixing m-cresol with p-cresol at a weight ratio of 6:4, adding formalin and condensing the mixture using an oxalic acid catalyst in accordance with a conventional procedure,

(B) 15 parts by weight of an alkali-soluble acrylic resin obtained by charging 200 g of propylene glycol methyl ether acetate as the solvent in a flask in which the atmosphere is replaced by nitrogen and stirring at 80° C.; preparing a polymerization mixture comprising 0.5 g of 2,2′-azobisisobutyronitrile as a polymerization initiator (manufactured by Wako Pure Chemical Industries, Ltd. under the trade name of V-65), 130 g of 2-methoxyethyl acrylate, 50.0 g of benzyl methacrylate and 20.0 g of acrylic acid in a dropping tank, stirring at 80° C. until the polymerization initiator is dissolved, and adding drop wise the resulting polymerization solution uniformly to the flask containing the solvent over 3 hours, polymerizing the mixture at 80° C. for 5 hours and cooling to room temperature,

(C) 10 parts by weight of hexamethoxymethylated melamine (manufactured by SANWA CHEMICAL CO., LTD. under the trade name of NIKALAC Mw-100), and

(D) 0.3 parts by weight of an acid generator represented by the following chemical formula (3) were dissolved in 150 parts by weight of propylene glycol methyl ether acetate as the solvent, and filtering the solution through a membrane filter having a pore diameter of 1.0 μm to obtain a chemical amplification type resist composition (negative).

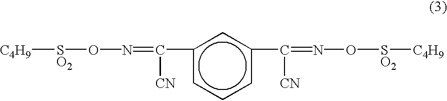

### Example 1

The shield layer material prepared in Synthesis Example 1 was applied onto a substrate (a) (copper sputter base, manufactured by OptoScience, Inc.) and heated at 160° C. for 10 minutes to obtain a shield layer (c) having a thickness of 0.2 μm.

Then, the chemical amplification type resist composition (negative) prepared in Synthesis Example 2 was applied and heated at 110° C. for 10 minutes to form a thick film photoresist layer (b) having a thickness of 65 μm.

The layer was irradiated with g-, h- and i-ray light each having a wavelength within a range from 300 to 500 μm through a mask pattern and then heated at 110° C. for 2 minutes.

Subsequently, the development was carried out by using a developing solution (manufactured by TOKYO OHKA KOGYO CO., LTD. under the trade name of PMER P-7G) to remove the unexposed portion of the thick film photoresist layer (b) and the shield layer (c) under the thick film photoresist layer using a plasma ashing apparatus, thus forming a resist pattern.

The resulting resist pattern was observed by using a scanning electron microscope. As a result, it was found to have a good rectangular pattern free from scum (residue).

Then, holes formed in the resist pattern were plated using a plating solution (manufactured by EEJA Co., Ltd. under the trade name of CU200), thereby to embed a metal post (material copper).

Finally, the remaining resist pattern and the shield layer (c) were removed by a remover (manufactured by TOKYO OHKA KOGYO CO., LTD. under the trade name of Remover 710) to form a bump protruding from the substrate.

### Example 2

In the same manner as in Example 1, except for replacing the shield layer (c) by the following shield layer, a resist pattern and a bump were formed.

The resulting resist pattern was good because it was free from scum and had gloss.

(c) Shield Layer

Composition of shield layer material: PVA (polyvinyl alcohol) (manufactured by KURARAY CO., LTD. under the trade name of PVA-205)

Thickness of shield layer: 1 μm

### Comparative Example 1

Except for providing no shield layer (c), the same operation as in Example 1 was repeated to obtain a pattern, wherein the lower portion contacting the substrate (a) is thinner than the upper layer of the resist pattern, as a result of the effect of the substrate (a).

Therefore, the desired profusion could not be formed.

As is apparent from the above results, by providing the shield layer (c), the resist composition can react with high sensitivity in the thick film photoresist layer (b) to form a high-accuracy resist pattern.

As described above, in the present invention, the effect that the metal would exert on the thick film photoresist layer (b) is blocked by the shield layer (c) provided between the substrate (a) and the thick film photoresist layer (b), even though a metal is used in the substrate or wiring pattern. Therefore, lowering of the sensitivity of the thick film photoresist layer (b) can be prevented without inhibiting the action of an acid generated by irradiation with radiation in the thick film photoresist layer (b), which makes it possible to realize an intrinsic high sensitivity of the chemical amplification type resist composition.

What is claimed is:

1. A thick film photoresist layer laminate comprising:
a substrate (a), and
a thick film photoresist layer (b) containing a resin whose alkali solubility changes due to an action of an acid, and an acid generator, which are laminated via a shield layer (c) which prevents the substrate (a) from contacting the thick film photoresist layer (b).

2. The thick film photoresist layer laminate according to claim 1, wherein the thick film photoresist layer (b) has a thickness of 5 to 150 μm.

3. The thick film photoresist layer laminate according to claim 1, wherein the shield layer (c) has a thickness of 0.01 to 5 μm.

4. The thick film photoresist layer laminate according to claim 2, wherein the shield layer (c) has a thickness of 0.01 to 5 μm.

5. A method of manufacturing a thick film resist pattern, which comprises the steps of obtaining a thick film photoresist layer laminate comprising a substrate (a), a thick film photoresist layer (b) containing a resin whose alkali solubility changes due to an action of an acid, and an acid generator, which are laminated via a shield layer (c) which prevents the substrate (a) from contacting the thick film photoresist layer (b); selectively irradiating the laminate with radiation; and developing the laminate after the irradiation step to obtain a thick film resist pattern.

6. The method of manufacturing a thick film resist pattern according to claim 5, wherein the thick film photoresist layer (b) has a thickness of 5 to 150 μm.

7. The method of manufacturing a thick film resist pattern according to claim 5, wherein the shield layer (c) has a thickness of 0.01 to 5 μm.

8. The method of manufacturing a thick film resist pattern according to claim 6, wherein the shield layer (c) has a thickness of 0.01 to 5 μm.

9. A method of manufacturing a connecting terminal, which comprises the step of forming a connecting terminal made of a conductor at a non-resist portion of the thick film resist pattern obtained by using the method of manufacturing a thick film resist pattern of claim 5.

10. A method of manufacturing a connecting terminal, which comprises the step of forming a connecting terminal made of a conductor at a non-resist portion of the thick film resist pattern obtained by using the method of manufacturing a thick film resist pattern of claim 6.

11. A method of manufacturing a connecting terminal, which comprises the step of forming a connecting terminal made of a conductor at a non-resist portion of the thick film resist pattern obtained by using the method of manufacturing a thick film resist pattern of claim 7.

12. A method of manufacturing a connecting terminal, which comprises the step of forming a connecting terminal made of a conductor at a non-resist portion of the thick film resist pattern obtained by using the method of manufacturing a thick film resist pattern of claim 8.
